(19) United States
(12) Patent Application Publication
(10) Pub. No.: US 2002/0030513 A1
(43) Pub. Date: Mar. 14, 2002

(54) Logic circuit cell constituting an integrated circuit and cell library having a collection of logic circuit cells

(75) Inventor: Yoshiaki Toyoshima, Kashiwa-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 09/950,070

(22) Filed: Sep. 12, 2001

(30) Foreign Application Priority Data
Sep. 11, 2000 (JP) 2000-275333

(51) Int. Cl. H03K 19/094

(52) U.S. Cl. 326/112

(57) ABSTRACT

A logic circuit cell has a logic element and a buffer circuit. The logic element performs a logic function. The logic element is comprised of first transistors having a first threshold voltage. The buffer circuit is connected to an output terminal of the logic element. The buffer circuit is comprised of second transistors having a second threshold voltage lower than the first threshold voltage. The buffer circuit receives an output of the first transistors in the logic element and controls the output.

### CROSS-REFERENCE TO RELATED APPLICATIONS

This application is based upon and claims the benefit of priority from the prior Japanese Patent Application No. 2000-275333, filed Sep. 11, 2000, the entire contents of which are incorporated herein by reference.

### BACKGROUND OF THE INVENTION

1. Field of the Invention

The present invention relates to a logic circuit cell constituting an integrated circuit and a cell library having a collection of logic circuit cells and, in particular, used to form a standard cell type logic LSI.

2. Description of the Related Art

Generally, an integrated circuit (hereinafter referred to as an LSI) comprises logic gates, such as a NAND gate, and logic circuit components, such as a latch circuit and flip-flop circuit, connected together by connection lines, such as a metal, and, by doing so, realizes a predetermined logic function. In the designing of the LSI, the following method is used. Planar layout data of several hundreds of kinds of logic circuit cells are prepared as a library. The layout data of the LSI as a whole are prepared by the use of a place-and-route tool for automatically placing and routing these logic circuit cells.

By the way, now attention is paid to the individual cells in the actual layout of the LSI and, even if the cells have the same logic function, the capacity of a load to be driven usually differs due to a difference in the number of subsequent stage gates to be connected and in the length of the wiring lines, and so on. In order to secure a necessary maximal drive force, therefore, the size (gate width) of MOS type field effect transistors in a logic function cell section is set to a usually required maximal one. If, however, the so set cell and such cell library are used, an increase in their area and in a resultant dissipation power are involved even in a portion where no such a drive force is not required.

In the cell library, therefore, even if the logic circuit cells of the same logic function are involved, a plurality of cells of different drive forces are prepared. In the case of a two-input NAND gate, for example, not only a cell of a minimal drive force for realizing the logic function but also those cells of 2-, 4- and 8-fold drive forces are often prepared in the library.

These logic circuit cells of different drive forces are realized by, as shown in FIG. 1, adding a drive force controlling buffer circuit 12 to a basic cell 11 for realizing a logic function.

FIGS. 2A to 2D are logic circuit diagrams showing a logic circuit cell structure in the case where the unit cell 11 is comprised of a NAND gate circuit A. FIG. 2A shows a logic circuit cell of a basic (one-fold) drive force in which case it is comprised of a NAND gate circuit A only. FIG. 2B shows a logic circuit of a 2-fold drive force, FIG. 2C shows a logic circuit of a 4-fold drive force and FIG. 2D shows a logic circuit of a 8-fold drive force. In the case where the drive force of the logic circuit cell is of the 2-, 4- and 8-fold drive type, the logic circuit cell comprises a NAND gate circuit A and subsequent-stage buffer circuits B1 and B2. By varying the size (gate width) of the MOSFETs in the buffer circuit B2 as shown in FIGS. 2A to 2D, it is possible to realize a logic circuit cell of a varying drive force relative to the basic cell.

FIG. 3 shows a circuit arrangement of a NAND gate circuit A and buffer circuits B1, B2 corresponding to those shown in FIGS. 2B to 2D. As shown in FIG. 3, a final-stage buffer circuit B2 is comprised of transistors TR1, TR2. By enlarging the gate width of the transistors TR1, TR2 of the buffer circuit B2 in proportion to a drive force it is possible to realize a plurality of logic circuit cells of different drive forces corresponding to FIGS. 2B to 2D.

In order to suppress the dissipation power as the LSI, the width of transistors in the NAND gate circuit A of the basic gate function section is so set as to obtain a predetermined minimal drive force for each library. It is usually the practice that the gate width of transistors in the buffer circuit B2 is so selected as to be a multiple of the gate width of transistors in the NAND circuit A.

FIG. 4 is a table showing the width ratio of the transistor gates in the case where the logic circuit cell has a 2-, 4- and 8-fold drive force.

In the technique for enlarging the width of the transistor gate in proportion to a corresponding drive force, however, the area of the buffer circuit B2 section is increased so as to obtain a greater drive force. Since, further, the connection line connected to the logic circuit cell has a tendency for its length to be increased due to an increase in the size of the LSI, it becomes necessary to provide a cell of a relatively great drive force and, hence, a greater area is required to form the LSI. Generally, the increase of the logic circuit cell involves an increase in a parasitic capacitance load and, hence, a wasteful dissipation power.

### BRIEF SUMMARY OF THE INVENTION

A logic circuit cell according to an aspect of the present invention comprises a logic element performing a logic function, the logic element being comprised of first transistors having a first threshold voltage, and a buffer circuit connected to an output terminal of the logic element and comprised of second transistors having a second threshold voltage lower than the first threshold voltage, the buffer circuit receiving an output of the first transistors in the logic element and controlling the output.

A cell library having a collection of logic circuit cells according to another aspect of the present invention comprises a plurality of logic elements performing logic functions, the logic elements each being comprised of first transistors having a first threshold voltage, and a plurality of buffer circuits each connected to an output terminal of the corresponding logic elements and each comprised of second transistors having a second threshold voltage lower than the first threshold voltage, and the buffer circuits each receiving an output of the corresponding first transistors and controlling the output.

### BRIEF DESCRIPTION OF THE SEVERAL VIEWS OF THE DRAWING

FIG. 1 is a diagram showing a structure of a conventional logic circuit cell;

FIGS. 2A to 2D, each, are a logic circuit diagram showing a circuit arrangement of the logic circuit cell;

FIG. 3 is a circuit diagram showing the logic circuit cell;

FIG. 4 is a table showing a transistor gate width ratio when a drive force of the logic circuit cell is varied;

FIG. 5 is a logic circuit diagram showing a logic circuit cell according to a first embodiment of the present invention;

FIG. 6 is a graph showing a variation of a drain current when a threshold voltage of MOSFETs in a buffer circuit of the logic circuit cell according to the first embodiment is varied;

FIG. 7 is a table showing threshold voltages and transistor gate width ratio when a drive force of the logic circuit cell according to the first embodiment is varied;

FIG. 8 is a graph showing a variation of a drain current when the thickness of a gate insulating film of MOSFETs in a buffer circuit of a logic circuit cell according to a second embodiment is varied; and

FIG. 9 is a table showing the thickness of the gate insulating film and transistor gate width ratio when a drive force of the logic circuit cell according to the second embodiment is varied.

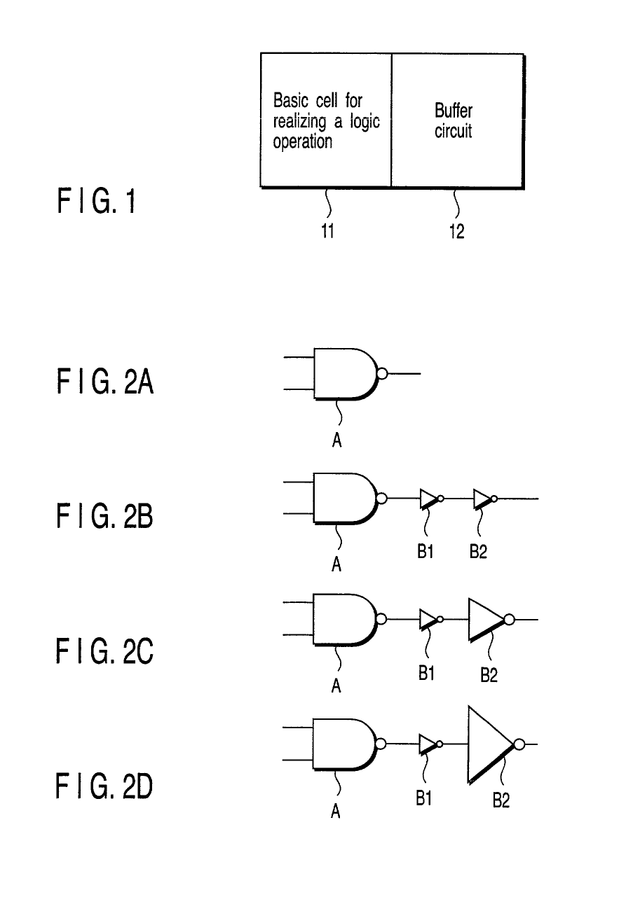

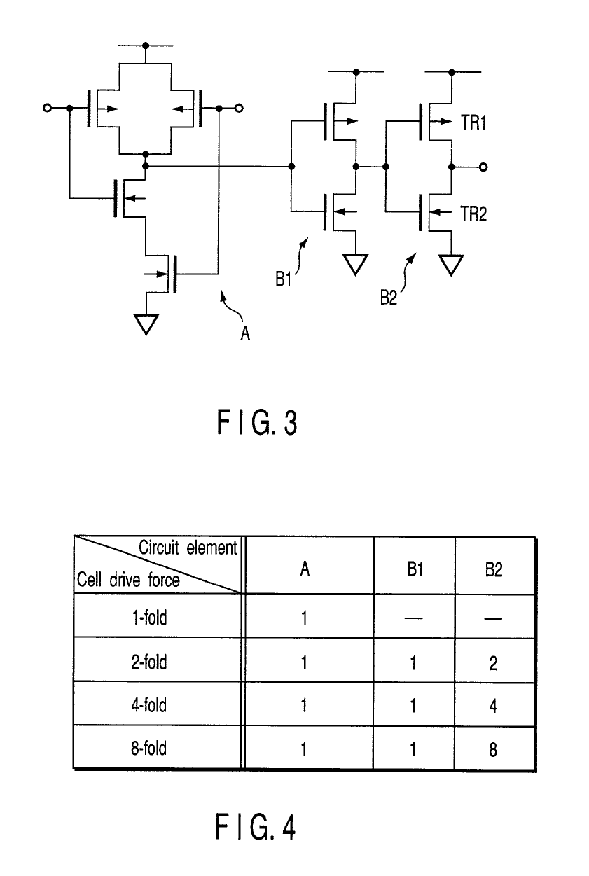

### DETAILED DESCRIPTION OF THE INVENTION

With reference to the drawing, an explanation will be made about a logic circuit cell constituting an LSI and a cell library having a collection of logic circuit cells according to the present invention.

First Embodiment

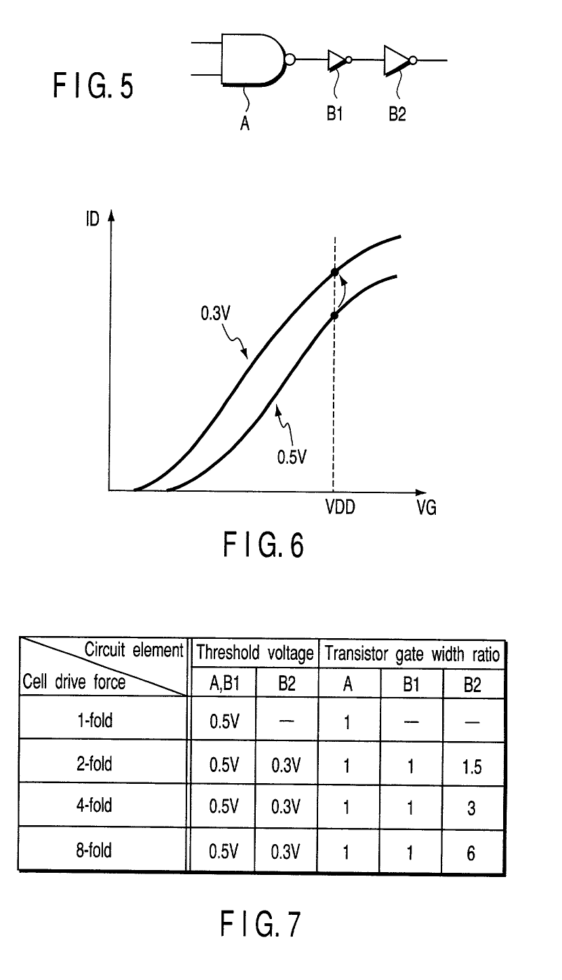

FIG. 5 is a logic circuit diagram showing a logic circuit cell according to a first embodiment of the present invention.

As shown in FIG. 5, the logic circuit cell comprises a NAND gate circuit A and subsequent-stage buffer circuits B1, B2. In the logic circuit cell, the NAND gate circuit A should be taken as one example and may be comprised of other elements so long as they are made up of a basic cell for realizing a logic element, that is, a logic element for performing a logic function. The buffer circuits B1, B2 constitute a two-stage inverter circuit and are adapted to control a drive force of the logic circuit cell.

The drive force of the logic circuit cell shown in FIG. 5 is decided by a drive force of the buffer circuit B2. It is to be noted that a predetermining minimal drive force is applied to the NAND gate circuit A and buffer circuit B1. In the first embodiment, the threshold voltage of MOS type field effect transistors (hereinafter referred to as MOSFETs) in the buffer circuit B2 is se to be lower than the threshold voltage of MOSFETs in the NAND gate circuit A and buffer circuit B1. By doing so, the drive force of the buffer circuit B2 is made greater and hence the drive force of the logic circuit cell is made greater.

Setting the threshold voltage of the MOSFETs in the buffer circuit B2 lower than the threshold voltage of the MOSFETs in the NAND gate circuit A and buffer circuit B1 is achieved by, for example, a method as will be set out below.

For example, let a power supply voltage VDD to be 1.8V and the threshold voltage of the MOSFETs of the NAND gate circuit A and buffer circuit B1 to be 0.5V. In the MOSFETs of the buffer circuit B2, the impurity concentration of a channel region is made lower than that of a channel region of the MOSFETs of the NAND gate circuit A and buffer circuit B1. By doing so, the threshold voltage of the MOSFETs of the buffer circuit B2 is made lower and is set to be about 0.3V.

FIG. 6 is a graph showing a variation in the drain current of the MOSFET when the threshold voltage is varied. As evident from FIG. 6, with the threshold voltage set to be 0.3V, a drain current ID is increased in comparison with the case where the threshold voltage is set to be 0.5V. Thus, if the threshold voltage of the MOSFETs of the buffer circuit B2 is set to be lower than the threshold voltage of the MOSFETs of the NAND gate circuit A and buffer circuit B1, it is possible to increase a drive force of the logic circuit cell.

FIG. 7 is a table showing the transistor gate width ratio and the threshold voltages when the drive force of the logic circuit cell is set to be a 2-, 4- and 8-fold. As evident from a comparison between FIG. 7 and FIG. 4, according to the first embodiment, a high drive force the same as in the prior art technique can be realized with the use of the buffer circuit B2 comprised of MOSFETs having a gate width smaller than that of the conventional ones.

In the first embodiment, as set out above, in the formation of an integrated circuit using a plurality of logic circuit cells and a cell library having a collection of such logic circuit cells based on pattern data for forming a circuit having a logic function, it is possible to realize a logic circuit cell and cell library without involving an increase of an area and dissipation power necessary to the formation of such integrated circuit and do so even if the logic circuit cell requires a greater drive force.

Second Embodiment

In the logic circuit cell shown in FIG. 5, the first embodiment is provided according to which the drive force of the logic circuit is increased by setting the threshold voltage of the MOSFETs of the buffer circuit B2 to be lower. In the second embodiment, on the other hand, the drive force of a logic circuit cell is increased by making the thickness of a gate insulating film of MOSFETs of a buffer circuit B2 smaller as will be set out below by way of example.

As set out above, the drive force of the logic circuit cell shown in FIG. 5 is decided by the drive force of the buffer circuit B2. It is to be noted that a predetermined minimal drive force is applied to the NAND gate circuit A and buffer circuit B1. In order to control the drive force of the buffer circuit B2, the second embodiment is so formed as to make the thickness of the gate insulating film of the MOSFETs of the buffer circuit B2 smaller than the thickness of the gate insulating film of MOSFETs in a NAND gate circuit A and buffer circuit B1. By doing so, the drive force of the buffer circuit B2 and, hence, a drive force of the logic circuit cell are increased.

For example, the thickness of the gate insulating film of MOSFETs in the NAND gate circuit A and buffer circuits B1, B2 are so set as will be set out below. A power supply voltage is set to be 1.8V and the thickness of the gate insulating film of the MOSFETs in the NAND gate circuit A and buffer circuit B1 is set to be about 4 nm. And the thickness of a gate insulating film of the MOSFETs in the buffer circuit B2 is set to be about 3 nm.

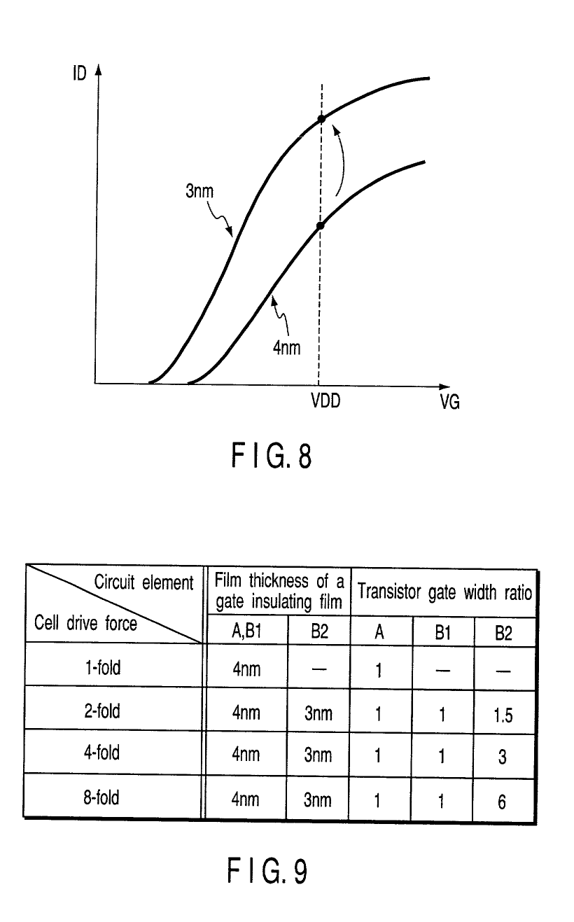

FIG. 8 is a graph showing a variation of a drain current in the MOSFET when the thickness of the gate insulating film is varied. As evident from FIG. 8, if the thickness of the gate insulating film is set to be 3 nm, then a drain current ID is increased in comparison with the case where the thickness of the gate insulating film is set to be 4 nm. If, therefore, the thickness of the gate insulating film of the MOSFET of the buffer circuit B2 is set to be smaller than the thickness of the gate insulating film of the MOSFETs in the NAND gate circuit A and buffer circuit B1, it is possible to increase a drive force of a resultant logic circuit cell.

FIG. 9 is a table showing the ratio of the transistor gate widths, as well as the thickness of the gate insulating film, when the drive force of the logic circuit cell is 2-, 4- and 8-fold. As evident from a comparison between FIG. 9 and FIG. 4, according to the second embodiment, a high drive force the same as that of the prior art logic circuit cell can be realized with the use of the buffer circuit B2 comprised of MOSFETs having a gate insulating film thinner than that of the prior art logic circuit cell.

In the second embodiment, as set out above, in the formation of an integrated circuit using a plurality of logic circuit cells and a cell library having a collection of such logic circuit cells based on pattern data for forming a circuit having a logic function, it is possible to realize a logic circuit cell and cell library without involving an increase of an area and dissipation power necessary to the formation of such integrated circuit and do so even if the logic circuit cell requires a greater drive force.

Although an adequate advantage is obtained even using only one of the above-mentioned first and second embodiments, it is possible to obtain a logic circuit cell of smaller size and still higher drive force with the joint use of both the features of the first and second embodiments.

According to the embodiments of the present invention it is possible to realize a logic circuit cell having a different current drive capability but having the same logic function and, hence, to achieve an enhanced integration LSI version of lower dissipation power.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A logic circuit cell comprising:
a logic element performing a logic function, the logic element being comprised of first transistors having a first threshold voltage; and
a buffer circuit connected to an output terminal of the logic element, the buffer circuit being comprised of second transistors having a second threshold voltage lower than the first threshold voltage, the buffer circuit receiving an output of the first transistors in the logic element and controlling the output.

2. The logic circuit cell according to claim 1, wherein the first transistors in the logic element have a first gate insulating film and the second transistors in the buffer circuit have a second gate insulating film, the thickness of the second gate insulating film being smaller than that of the first gate insulating film.

3. The logic circuit cell according to claim 1, wherein the buffer circuit is comprised of a plurality of inverter circuits.

4. A logic circuit cell comprising:
a logic element performing a logic function, the logic element being comprised of first transistors having a first threshold voltage;
a first inverter circuit connected to an output terminal of the logic element, the first inverter circuit being comprised of second transistors having a second threshold voltage; and
a second inverter circuit connected to an output terminal of the first inverter circuit, the second inverter circuit being comprised of third transistors having a third threshold voltage lower than the first and second threshold voltages.

5. The logic circuit cell according to claim 4, wherein the first transistors in the logic element have a first gate insulating film, the second transistors in the first inverter circuit have a second gate insulating film, and the third transistors in the second inverter circuit have a third gate insulating film, the thickness of the third gate insulating film being smaller than the thickness of the first and second gate insulating films.

6. The logic circuit cell according to claim 4, wherein the first threshold voltage of the first transistors in the logic element is equal to the second threshold voltage of the second transistors in the first inverter circuit.

7. The logic circuit cell according to claim 4, wherein a drive force of the second inverter circuit is greater than a drive force of the logic element.

8. A logic circuit cell comprising:
a logic element performing a logic function, the logic element being comprised of first transistors having a first gate insulating film; and
a buffer circuit connected to an output terminal of the logic element, the buffer circuit being comprised of second transistors having a second gate insulating film of a thickness smaller than the thickness of the first gate insulating film and the buffer circuit receiving an output of the first transistors in the logic element and controlling the output.

9. The logic circuit cell according to claim 8, wherein the first transistors in the logic element have a first threshold voltage and the second transistors in the buffer circuit have a second threshold voltage, the second threshold voltage being lower than the first threshold voltage.

10. The logic circuit cell according to claim 8, wherein the buffer circuit has a plurality of inverter circuits.

11. A logic circuit cell comprising:
a logic element performing a logic function, the logic element being comprised of first transistors having a first gate insulating film;
a first inverter circuit connected to an output terminal of the logic element, the first inverter circuit being comprised of second transistors having a second gate insulating film; and
a second inverter circuit connected to an output terminal of the first inverter circuit, the second inverter circuit being comprised of third transistors having a third gate insulating film of a thickness smaller than the thickness of the first and second gate insulating films.

12. The logic circuit cell according to claim 11, wherein the first transistors in the logic element have a first threshold voltage, the second transistors in the first inverter circuit have a second threshold voltage and the third transistors in the second inverter circuit have a third threshold voltage, the third threshold voltage being lower than the first and second threshold voltages.

13. The logic circuit cell according to claim 11, wherein the thickness of the first gate insulating film of the first transistors in the logic element is equal to the thickness of the second gate insulating film of the second transistors in the first inverter circuit.

14. The logic circuit cell according to claim 11, wherein a drive force of the second inverter circuit is greater than a drive force of the logic element.

15. A cell library having a collection of logic circuit cells, comprising:
a plurality of logic elements performing logic functions, the logic elements each being comprised of first transistors having a first threshold voltage; and
a plurality of buffer circuits each connected to an output terminal of the corresponding logic elements, the buffer circuits each being comprised of second transistors having a second threshold voltage lower than the first threshold voltage, and the buffer circuits each receiving an output of the corresponding first transistors and controlling the output.

16. The cell library according to claim 15, wherein the first transistors in the logic element have a first gate insulating film and the second transistors in the buffer circuit have a second gate insulating film, the thickness of the second gate insulating film being smaller than the thickness of the first gate insulating film.

17. The cell library according to claim 15, wherein the buffer circuits, each, have a plurality of inverter circuits.

18. A cell library having a collection of logic circuit cells, comprising:
a plurality of logic elements performing logic functions, the logic elements each being comprised of first transistors having a first gate insulating film; and
a plurality of buffer circuits each connected to an output terminal of the corresponding logic elements, the buffer circuits each being comprised of second transistors having a second gate insulating film of a thickness smaller than the thickness of the first gate insulating film, the buffer circuits each receiving an output of the corresponding first transistors in the logic element and controlling the output.

19. The cell library according to claim 18, wherein the first transistors in the logic element have a first threshold voltage and the second transistors in the buffer circuit have a second threshold voltage, the second threshold voltage being lower than the first threshold voltage.

20. The cell library according to claim 18, wherein the buffer circuits, each, have a plurality of inverter circuits.
